(19) United States
(12) Patent Application Publication
(10) Pub. No.: US 2006/0003566 A1
(43) Pub. Date: Jan. 5, 2006

(54) Methods and apparatuses for semiconductor fabrication utilizing through-wafer interconnects

(76) Inventor: Ismail Emesh, Gilbert, AZ (US)

Correspondence Address: INGRASSIA FISHER & LORENZ, P.C., 7150 E. CAMELBACK, STE. 325, SCOTTSDALE, AZ, 85251, US

(21) Appl. No.: 10/882,481

(22) Filed: Jun. 30, 2004

(51) Int. Cl. H01L 21/44; H01L 21/4763

(52) U.S. Cl. 438/597

(57) ABSTRACT

Methods are provided for forming semiconductor packages utilizing a device-ready wafer having a through-wafer via interconnect. One exemplary method comprises etching a via extending from a first surface of the device-ready wafer and terminating within the wafer. The first surface of the device-ready wafer is contacted with a wafer contact surface while relative motion between the device-ready wafer and the wafer contact surface is effected. An electrochemical deposition composition comprising a conductive material is supplied to the first surface of the wafer and an electric potential difference is applied between the first surface of the wafer and an anode. Conductive material is deposited within the via and a portion of the wafer is removed from a second surface of the wafer to expose the conductive material within the via.

### FIELD OF THE INVENTION

The present invention generally relates to semiconductor fabrication, and more particularly relates to methods and apparatuses for semiconductor fabrication utilizing through-wafer interconnects.

### BACKGROUND OF THE INVENTION

The current trends in high performance integrated circuits are towards faster and more powerful circuits in the giga-hertz range and even further. As more complex integrated circuits (ICs) such as microprocessors have been entering the giga-hertz operating frequency range, various speed-related roadblocks have become increasingly difficult to overcome. One of the more serious impediments is increasingly becoming the global interconnect. ICs are using a greater fraction of their clock cycles charging interconnect wires. As global interconnects become longer and more numerous in integrated circuits, RC delay and power consumption are becoming limiting factors.

One proposed solution to the problems with global interconnects is three-dimensional chip packaging. Three-dimensional chip packaging refers to the vertical (z-axis) stacking of multiple die within a package or multiple packages utilizing specialized interconnects. These specialized interconnects are “through-wafer vias” that extend through one or more of the chips and that are aligned when the chips are stacked to provide electrical communication between the stacked chips. Three-dimensional packaging may result in reductions of size and weight of a chip package, reduction in power consumption, and an increase in performance and reliability.

The through-wafer vias used in three-dimensional technology tend to be larger in dimension than intra-wafer (e.g., device) vias. Typically, through-wafer vias may have widths as large as about 100 to 150 μm or greater. Present-day technology used to fabricate such relatively large vias has proven unsatisfactory. To fabricate the vias, it is necessary to fill the vias with a conductive material, typically a metal. However, to adequately fill such wide features, it is often necessary to deposit relatively thick layers of the metal over the surface of the workpiece. A subsequent planarization process then is required to remove excess metal on the workpiece and to level the surface of the workpiece as needed for further integrated circuit manufacturing. Such planarization processes typically include chemical mechanical planarization processes, which mechanically remove the thick excess metal layer, reverse polarity deposition processes, which electrically remove the thick excess metal layer, or wet etches, which chemically remove the thick excess metal layer. Deposition of such thick layers of metal followed by a planarization process to subsequently remove the thick excess metal layer increases the costs of the fabrication and decreases throughput. The subsequent planarization process also may result in pitting, cracking, or scratching of the underlying work piece.

Accordingly, it is desirable to provide a method of forming a semiconductor package with reduced wafer processing time. In addition, it is desirable to provide a method for forming through-wafer vias within a wafer with reduced processing steps. It also is desirable to provide an apparatus that is configured to perform methods for forming through-wafer vias within a wafer. Furthermore, other desirable features and characteristics of the present invention will become apparent from the subsequent detailed description of the invention and the appended claims, taken in conjunction with the accompanying drawings and this background of the invention.

### BRIEF DESCRIPTION OF THE DRAWINGS

The present invention will hereinafter be described in conjunction with the following drawing figures, wherein like numerals denote like elements, and

FIGS. 1-10 are cross-sectional views of a method for fabricating a semiconductor package in accordance with one exemplary embodiment of the present invention;

FIG. 11 is a cross-sectional view of an electrochemical mechanical deposition apparatus in accordance with an exemplary embodiment of the present invention;

FIGS. 12-18 are cross-sectional views of a method for fabricating a semiconductor package in accordance with another exemplary embodiment of the present invention;

FIG. 19 is a top cut-away illustration of a multi-process apparatus that may be used to perform a method of the present invention;

FIG. 20 is a top cut-away illustration of another multi-process apparatus that may be used to perform a method of the present invention; and

FIG. 21 is a bottom cut-away illustration of a carousel for use with the multi-process apparatus of FIG. 20.

### DETAILED DESCRIPTION OF THE INVENTION

The following detailed description of the invention is merely exemplary in nature and is not intended to limit the invention or the application and uses of the invention. Furthermore, there is no intention to be bound by any theory presented in the preceding background of the invention or the following detailed description of the invention.

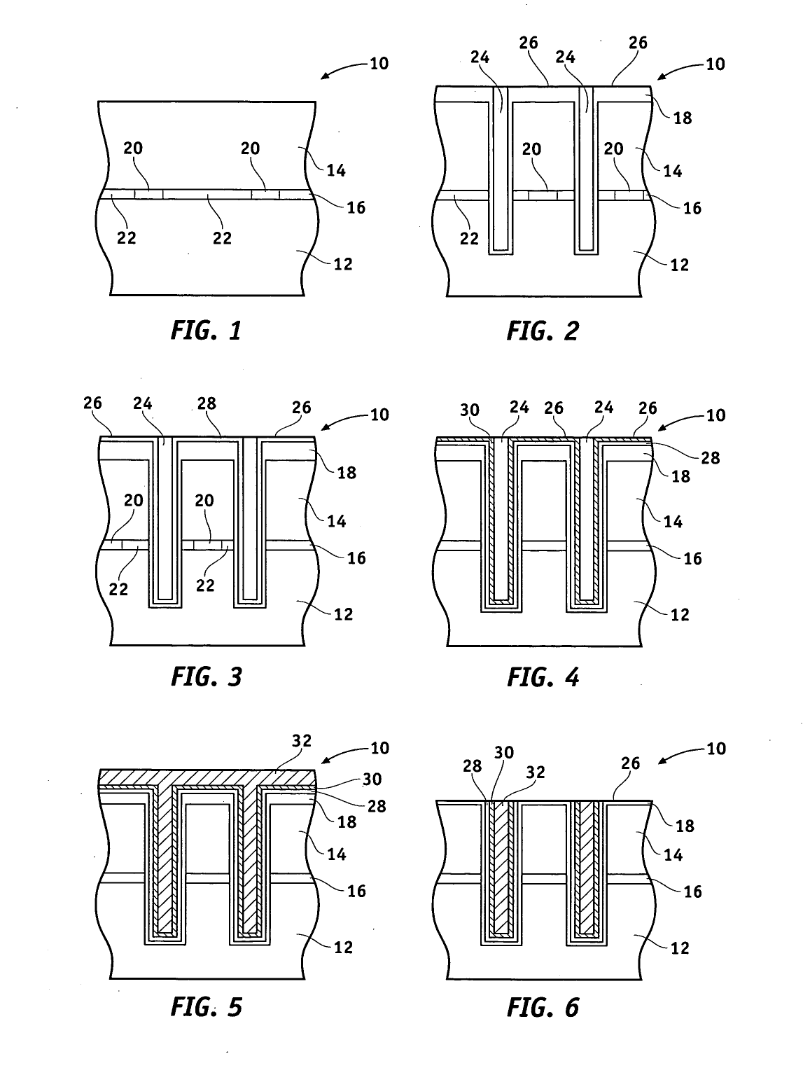

FIGS. 1-8 illustrate a method for fabricating a semiconductor package in accordance with one exemplary embodiment of the present invention. Referring to FIG. 1, the method begins with a first device-ready wafer 10. First device-ready wafer 10 comprises a semiconductor substrate layer 12, which may be any suitable semiconductor substrate material, such as, for example, silicon, silicon-on-insulator (SOI), or gallium arsenide, and may have any suitable thickness. A device layer 16 overlies substrate layer 12 and may comprise one or more device elements 20, such as transistors, memory devices, and the like, formed within an insulating material 22. The insulating material 22 may comprise silicon dioxide, silicon nitride or any of the other insulating materials commonly used in the fabrication of semiconductor devices. In a preferred embodiment of the invention, dielectric material 22 comprises silicon dioxide. A first dielectric layer 14 overlies device layer 16 and may comprise any suitable number of multi-level interconnects (not shown), including multi-level interconnects in electrical communication with device elements 20 disposed within device layer 16. Although shown as only single dielectric layers, first dielectric layer 14 and insulating material 22 each may be a single layer of dielectric material or may be composed of a plurality of layers of dielectric material, not all of which are necessarily the same material. First dielectric layer 14 may comprise any conventional dielectric material known in the semiconductor industry and may comprise the same dielectric material that forms insulating material 22. In accordance with one embodiment of the invention, first dielectric layer 14 may include a layer of low-k dielectric material such as those formed by spin on deposition from, for example, an organic source material comprising polimide, silicon sesquioxane, siloxane, or the like. By low-k dielectric material is meant a material having a dielectric constant less than about 3.9. Preferably, first dielectric layer 14 comprises silicon dioxide. In one embodiment of the invention, first dielectric layer 14 and device layer 16 comprise one integral layer. In an alternative embodiment, dielectric layer 14 and device layer 16 are two separate layers formed at different times. It will also be appreciated that first device-ready wafer 10 may comprise one or more device layers in addition to device layer 16 and may comprise one or more dielectric layers in addition to first dielectric layer 14.

Referring to FIG. 2, at least one through-wafer via 24 is formed within first device-ready wafer 10. Through-wafer via 24 may be formed by conventional photolithographic techniques and etching techniques. Through-wafer via 24 extends from a first surface 26 of first device-ready wafer 10 through dielectric layer 14 and device, layer 16 and terminates within substrate layer 12. In one embodiment of the invention, the width of through-wafer via 24 may be in the range of from about 0.1 μm to about 150 μm and the depth may be in the range of from about 10 μm to about 100 μm.

In an optional embodiment of the present invention, a second dielectric layer 18 may be formed overlying the first surface 26 of first device-ready wafer 10 and within through-wafer via 24. Second dielectric layer 18 serves as a barrier against diffusion of a subsequently deposited metal into semiconductor substrate 12 and into first dielectric layer 14 and device layer 16. Second dielectric layer 18 may also be used for subsequent interconnect formation after formation of through-wafer via 24. Second dielectric layer 18 may be formed of any suitable, conventional dielectric material, such as, for example, silicon dioxide or silicon nitride and may be formed by any suitable method known in the industry, such as, for example, plasma vapor deposition (PVD), chemical vapor deposition (CVD), atomic layer deposition (ALD), and the like to any suitable thickness. In another optional embodiment of the present invention, second dielectric layer 18 may be formed in two steps. In this regard, a second dielectric layer may be formed overlying first dielectric layer 14 before through-wafer via 24 is formed. After formation of through-wafer via 24, dielectric material may be formed on the bottom and sidewalls of the via.

Turning to FIG. 3, in one embodiment of the invention a barrier layer 28 subsequently may be deposited overlying the bottom and sidewalls of through-wafer via 24 and the first surface 26 of first device-ready wafer 10. Barrier layer 28 may comprise any material suitable for minimizing the diffusion of a conductive material, such as copper, that is used to fill through-wafer via 24, as discussed in more detail below. Suitable materials from which barrier layer 28 may be formed include silicon dioxide, titanium nitride, tantalum, tantalum nitride, and the like. Barrier layer 28 may be formed of one or more than one layer of materials and may be formed by any suitable method known in the industry, such as, for example, PVD, CVD, and the like, to any suitable thickness, such as, for example, about 25 nm or less.

Referring to FIG. 4, in another embodiment of the invention, after formation of barrier layer 28, a seed layer 30 of conductive material may be formed on barrier layer 28 overlying the sidewalls and bottom of through-wafer via 24 and the first surface 26 of first device-ready wafer 10. The seed layer 30 may comprise any suitable conductive material, such as, for example, copper, and may be formed by any suitable method known in the industry, such as, for example, sputtering, PVD or CVD. The seed layer also may be formed using electroless deposition methods, such as the electroless deposition method described in U.S. Pat. No. 6,664,122, issued on Dec. 16, 2003 to Andryuschenko et al., which patent is incorporated in its entirety herein by reference.

Next, as illustrated in FIG. 5, a layer 32 of conductive material is deposited overlying the seed layer 30 by an electrochemical mechanical deposition process, also known as a planar plating process, such as that disclosed in the copending, commonly assigned U.S. application Ser. No. 10/377488, filed Feb. 27, 2003, the disclosure of which is herein incorporated in its entirety by reference. The conductive material layer 32 is formed from any suitable conductive material, such as copper, and preferably is formed of the same conductive material from which seed layer 30 is formed. In a more preferred embodiment, seed layer 30 and conductive material layer 32 both comprise copper. The electrochemical deposition process continues for a predetermined amount of time or until an endpoint detection apparatus indicates that a desired deposition thickness has been achieved. The electrochemical mechanical deposition process results in the deposition of the conductive material layer 32 such that through-wafer via 24 is completely filled with the conductive material, while conductive material layer 32 maintains a substantially planar surface.

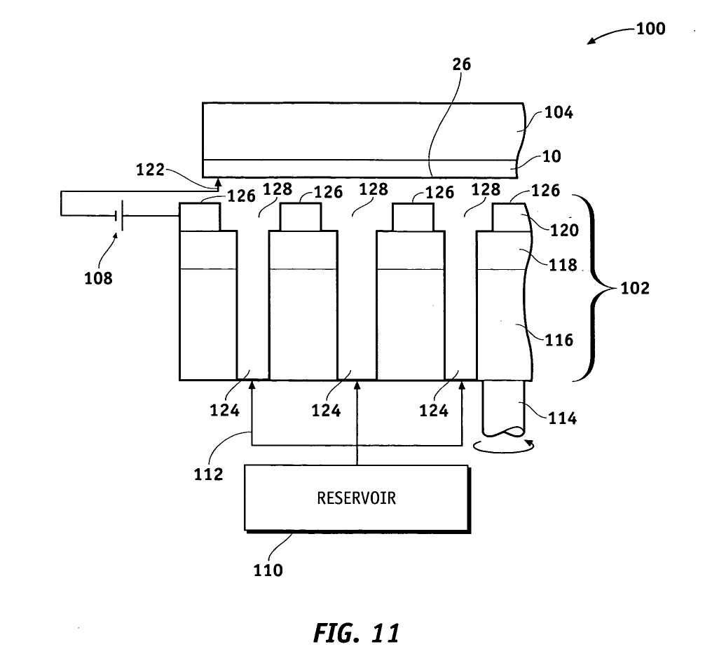

As described below in more detail, the conductive material layer 32 can be deposited in a variety of different deposition apparatuses. Referring momentarily to FIG. 11, an electrochemical mechanical deposition apparatus 100 utilized in accordance with one exemplary embodiment of the present invention is schematically illustrated. Electrochemical mechanical deposition apparatus 100 may be configured to perform electrochemical mechanical deposition, electrochemical planarization, and/or polishing utilizing a platen/wafer contact surface stack 102. Electrochemical mechanical deposition apparatus 100 includes the stack 102 and a wafer carrier assembly 104 configured to carry first device-ready wafer 16 by any method known in the industry, such as, for example, vacuum suction or suitable wafer grippers. Electrochemical mechanical deposition apparatus 100 further comprises a source of potential 108, a reservoir 110 for receiving and holding an electrochemical deposition composition 112, and a drive controller 114.

Stack 102 comprises a support member or platen 116, a conductive member 118 disposed overlying platen 116, and a wafer contact surface 120 disposed overlying the conductive member 118. Platen 116 may be fabricated from any suitable non-compressible material, such as, for example, a ceramic or stainless steel. Conductive member 118 may be fabricated from a conductive material, such as copper, tantalum, gold or platinum, or may be formed of an inexpensive material, such as aluminum, and coated with a conductive material.

Wafer contact surface 120 may be suitably formed of an insulating material such as a polymeric material, a polymetric/inorganic composite “fixed abrasive” material, or a ceramic insulator material as are used in chemical mechanical polishing of conductive films. Blown polyurethane pads, such as the IC and GS series of pads available from Rodel Products Corporation of Scottsdale, Ariz., may be advantageously used, with the added benefit of being capable of also polishing wafer 10 in a chemical mechanical polishing step, although it will be appreciated that any suitable polishing pad or surface may be used in accordance with the present invention. If wafer contact surface 120 is of an insulative type, it may comprise one or more orifices 128, which may or may not be coaxial with channels 124 described in more detail below, so that wafer 10 may experience an electric potential.

In another embodiment, the wafer contact surface 120 may be formed from a material exhibiting a low coefficient of surface friction, and a relatively smooth surface finish. It has been found that smooth, low friction surfaces can enhance the deposition process by minimizing mechanical abrasion of the metal film being formed on the wafer in situations where the contact surface 120 is in actual contact with the surface of the wafer. Preferably the surface 120 is formed from a material with a coefficient of surface friction of less than about 0.2, and more preferably between 0.06 and 0.1. The surface roughness is preferably less than about 100 micro-inches per inch, and more preferably between about 10 and 50 micro-inches per inch. One skilled in the art will recognize that the actual surface finish can be tailored within these ranges by lapping or polishing the surface 120 as required.

The wafer contact surface 120 also may be formed of a material that is relatively volume incompressible under an applied pressure load. Volume compressibility can be defined in terms of the bulk modulus, or hydrostatic modulus of the material, and represents the change in volume that occurs in a material under hydrostatic loading, i.e. with pressure applied from all sides. The higher the compressibility of a material, the greater the volume change under an applied pressure load. Preferably the bulk modulus, or compressibility, of surface 120 is greater than about 50,000 pounds per square inch (psi) under an applied surface pressure of less than 4 psi, and greater than about 70,000 psi under an applied surface pressure of less than 2 psi. Suitable materials with the above properties include non-porous polymers such as, for example, molded polytetrafluoroethylene (PTFE), available from DuPont under the trade name Teflon®. This material is also highly inert (i.e. chemically resistant), and its hardness is comparable to polyurethane polishing pads of the type referred to above typical for chemical-mechanical polishing of wafers. Other suitable materials from which wafer contact surface 120 may be manufactured include polyether ether keytone, acetyl homopolymer, polyethylene teraphthalate, polyphenol sulfide, and polyvinyl chloride.

During an electrochemical mechanical deposition process in accordance with the present invention, first device-ready wafer 10 may be urged against wafer contact surface 120 by wafer carrier assembly 104. It will be appreciated that, alternatively, wafer contact surface 120 may be urged against first device-ready wafer 10 by drive controller 114. Preferably, first device-ready wafer 10 experiences a uniform and constant pressure of approximately one pound per square inch (psi) or less, although it may be appreciated that any suitable pressure that promotes substantially planar deposition may be used. Using source of potential 108, the apparatus applies a negative potential to the wafer 10 through a cathode contact 122, and a positive potential to conductive member 118, which acts as an anode. Cathode contact 122 may comprise one or more contacts and may contact wafer 10 by a variety of methods. For example, contact 122 may be insulated from and disposed within platen 116, conducting member 118, and wafer contact surface 120 to contact the face of wafer 10, or may be disposed remote from stack 102 to contact the face of wafer 10 at its peripheral edge. The source of potential 108 may apply a constant current or voltage to the apparatus or, alternatively, the current or voltage could be modulated to apply different currents or voltages at predetermined times in the process or to modulate between a predetermined current or voltage and no current or no voltage.

Platen 116 is connected to drive controller 114 that is operative to rotate stack 102 about a vertical axis. It will be appreciated by those of skill in the art, however, that drive controller 114 may be operative to move stack 102 in an orbital, linear or oscillatory pattern, or any combination thereof. Similarly, wafer carrier assembly 104 may be connected to a drive controller or motor assembly (not shown) that is operative to rotate wafer carrier assembly 104 and wafer 10 about a vertical axis or to move wafer carrier assembly 104 and the wafer 10 in an orbital, linear or oscillatory pattern or any combination thereof.

Platen 116 and conducting member 118 may have one or more channels 124 for the transportation of the electrochemical deposition composition 112 to wafer contact surface 120 from reservoir 110 via a manifold apparatus (not shown) or any suitable distribution system. In one embodiment of the invention, wafer contact surface 120 also has channels that are coaxial with channels 124 and that permit the flow of the electrochemical deposition composition to wafer 10 before and/or during an electrochemical mechanical deposition process. In another embodiment of the invention, channels 124 lead the electrochemical deposition composition to the wafer contact surface 120 that is formed from a porous material that absorbs the composition and allows the composition to flow through the pores to a surface 126 of the wafer contact surface for contact with wafer 10. Alternatively, it will be appreciated that the electrochemical deposition composition may be deposited directly onto or through wafer contact surface 120 by a conduit or any suitable application mechanism.

The electrochemical deposition composition 112 is formulated so that the amount of “overburden”, that is, the amount of conductive material deposited onto first surface 26 of wafer 10, is substantially less than the amount of overburden produced during conventional electroplating. During conventional electroplating, the rate of deposition of conductive material within the via is approximately equal to the rate of deposition of conductive material on the surface of the wafer (i.e., the rate of deposition of overburden). However, during the electrochemical mechanical deposition process of the present invention, the rate of deposition of the conductive material in the via may be greater, even two (2) to five (5) times or more greater, than the rate of deposition of overburden. This “single-step” electrochemical mechanical deposition thus reduces, or may eliminate altogether, the time and cost of subsequent processing steps, such as wet etching, chemical mechanical planarization, reverse polarity etching and the like, to remove excessive overburden.

In one embodiment of the invention, the composition suitably comprises a metal salt, at least one suppressor, and at least one accelerator. Suitable suppressors in accordance with the various embodiments of the present invention may comprise any suitable polymer that is soluble in water and has a molecular weight in the range of from b 1000 to 2 million. In a preferred embodiment of the invention, the suppressor comprises block copolymers of ethylene oxide and propylene oxide. Examples of block copolymers of ethylene oxide and propylene oxide that may be used in the electrochemical deposition composition may include Pluronic®, Pluronic®, Tetronic®, and Tetronic® R surfactants manufactured by BASF Corporation of Mount Olive, N.J. In a more preferred embodiment of the invention, the polymer suppressors may comprise one or more of the surfactants Pluronic® L62LF, L72, L92, L122, 17R1, 25R1, 25R2, 31R1, and 31R2. Suitable accelerators may comprise compounds that contain one or more sulfur atoms and have a molecular weight of about 1000 or less. In one exemplary embodiment, the accelerators may comprise compounds having the formula H—S—R or —S—S—R, where R is an electron-donating group that may increase electron density on the sulfur atom and impart stability to the accelerator anion that is created in solution. Examples of suitable accelerators include dipropyl sulfide, tert-butyl disulfide, 3,3′-dithiodipropionic acid, a metal salt of 2-mercaptoethane sulfonic acid, and a metal salt of 3-mercaptopropane sulfonic acid, where the metal salt may comprise sodium, potassium, ammonium, and the like.

In another exemplary embodiment of the invention, after formation of seed layer 30, an accelerator may be applied to wafer 10 so that before or during electrochemical mechanical deposition, the accelerator resides predominantly, if not exclusively, within through-wafer via 24 relative to first surface 26 of wafer 10. The accelerator may be applied to wafer 10 using a process such as that described in commonly assigned U.S. application Ser. No. 10/739,822, filed Dec. 17, 2003, which is herein incorporated in it entirety by reference. In this regard, the accelerator may be applied to first device-ready wafer 10 so that the accelerator attaches or adheres to both first surface 26 of wafer 10 and the walls and bottom surface of through-wafer via 24. The accelerator may be applied to first device-ready wafer 10 by placing wafer 10 in a bath containing the accelerator or, alternatively, the accelerator may be sprayed onto wafer 10 or may be applied to wafer 10 by any other suitable mechanism. The accelerator then may be selectively removed from first surface 26 of wafer 10. In one embodiment of the invention, the accelerator may be applied to wafer 10 before it is selectively removed from first surface 26. Alternatively, in another embodiment of the invention, the accelerator may be applied to wafer 10 at the same time that it is removed from first surface 26 of wafer 10. The accelerator may be removed from first surface 26 by rubbing first surface 26 with a contact surface, such as wafer contact surface 120 of electrochemical mechanical deposition apparatus 100, or the accelerator may be removed by any other suitable mechanism, such as by a CMP pad in a CMP apparatus.

Conductive material layer 32 then may be deposited onto first device-ready wafer 10 in an electrochemical mechanical deposition apparatus, such as electrochemical mechanical deposition apparatus 100, using an electrochemical mechanical deposition composition comprising a metal salt, at least one suppressor, and an electrolyte. The conductive material will preferentially deposit in through-wafer via 24, where the accelerator remains. In one embodiment of the invention, application of the accelerator to wafer 10 may be performed in one or more apparatuses, and removal of the accelerator from first surface 26 of wafer 10 and electrochemical mechanical deposition on wafer 10 may be performed in an electrochemical mechanical deposition apparatus, such as electrochemical mechanical deposition apparatus 100. In another alternative embodiment of the invention, application of the accelerator to wafer 10 and removal of the accelerator from first surface 26 of wafer 10 may be performed in one or more apparatus, and deposition of the conductive material may be performed in an electrochemical mechanical apparatus, such as electrochemical mechanical apparatus 100. In yet another alternative embodiment of the invention, application of the accelerator, removal of the accelerator from first surface 26 of wafer 10, and electrochemical mechanical deposition on wafer 10 all may be performed in an electrochemical mechanical deposition apparatus, such as apparatus 100. In this regard, removal of the accelerator may occur before the electrochemical mechanical deposition process or may occur simultaneously with the electrochemical mechanical deposition process.

Following the deposition of conductive material layer 32 having a relatively thin overburden and a substantially planar upper surface, the excess conductive material and barrier layer overlying first surface 26 of dielectric layer 14 may be removed to achieve the desired structure illustrated in FIG. 6. Removal of the excess conductive material and barrier layer may be effected by a chemical mechanical planarization (CMP) process, electrochemical mechanical planarization (ECMP), wet etching, or any other suitable conventional removal method. In one embodiment of the invention, a portion of second dielectric layer 18, if present, and/or a portion of first dielectric layer 14 may be removed to ensure that the conductive material and barrier layer 28 have been substantially removed from first surface 26.

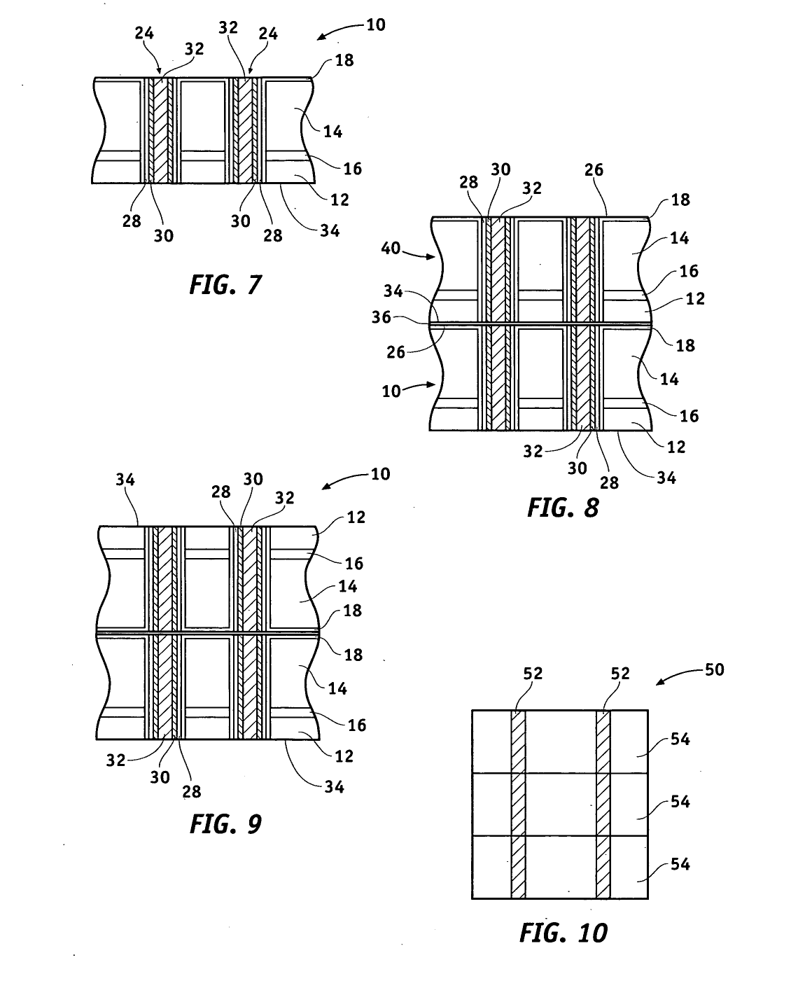

Referring to FIG. 7, a portion of semiconductor substrate 12 next is removed from a second surface 34 of wafer 10 to expose conductive material layer 32 within through-wafer via 24. In one embodiment of the invention, a portion of the semiconductor substrate 12 is removed before removal of the excess conductive material, as described above with reference to FIG. 6. In a preferred embodiment, a portion of the semiconductor substrate 12 is removed after removal of the excess conductive material. Semiconductor substrate 12 may be thinned using any suitable conventional method, such as mechanical grinding, wet or dry etching, CMP, and the like, or a combination of such methods. For example, in one embodiment of the invention, a first portion of semiconductor substrate 12 is removed by wet etching. A second portion of semiconductor substrate 12, a portion of second dielectric layer 18 and a portion of barrier layer 28 then may be removed from second surface 34 to expose conductive material layer 32 within through-wafer via 24. Semiconductor substrate 12 may be thinned to any suitable thickness. In one embodiment of the invention, the semiconductor substrate 12 is thinned to a thickness of no greater than about 100 μm. In a preferred embodiment of the invention, the semiconductor substrate 12 is thinned to a thickness of no greater than about 50 μm. In a more preferred embodiment, the semiconductor substrate 12 is thinned to a thickness of no greater than about 10 μm.

It will be appreciated that it may be difficult to hold and manipulate first device-ready wafer 10 due to its relatively small thickness, particularly after the semiconductor substrate 12 is thinned. Accordingly, it will be appreciated that, in one exemplary embodiment of the invention, first surface 26 of first device-ready wafer 10 may be affixed to another wafer or work piece, such as another device-ready wafer, that may serve as a “handle” for first device-ready wafer 10 to facilitate thinning of semiconductor substrate 12. The second wafer or work piece may be affixed to the first device-ready wafer 10 before through-wafer vias 24 are etched in first device-ready wafer 10. In this regard, through-wafer vias 24 then may be formed to extend from the second wafer or work piece to within first device-ready wafer 10 and the process may continue as described above. Alternatively, the second wafer or work piece may be affixed to first surface 26 of first device-ready wafer 10 after the removal of excess conductive material from first surface 26. In this regard, the second wafer also may comprise one or more through-wafer vias that are aligned with the through-wafer vias 24 of first device-ready wafer 24 during affixing of the device-ready wafers.

Referring to FIG. 8, wafer 10 then is affixed to a second device-ready wafer 40 in which through-wafer vias 24 also have been formed. Through-wafer vias 24 of wafer 10 are aligned with through-wafer vias 24 of wafer 40 and the wafers are bonded using any conventional glue or adhesive 36 known in the semiconductor industry, such as, for example, benzocyclobutene (BCB) or fluorinated poly(arylene) ether (FLARE). Through-wafer vias 24 within wafer 40 may be formed using the method as described above or may be formed using any other suitable method. In one embodiment of the invention, wafer 10 and wafer 40 may be bonded “face-to back”, that is, first surface 26 of wafer 10 is bonded to a second surface 34 of wafer 40, as illustrated in FIG. 8. In an alternative embodiment of the invention, wafer 10 and wafer 40 may be bonded “face-to-face”, that is, first surface 26 of wafer 10 is bonded to a first surface 26 of wafer 40, as illustrated in FIG. 9. As will be appreciated, wafer 10 and/or wafer 40 each then may be bonded to another device-ready wafer having through-wafer vias to form the stacked chip package 50 shown in FIG. 10 having bonded wafers 54 and aligned through-wafer vias 52. While stacked chip package 50 is illustrated in FIG. 10 with three (3) bonded wafers, it will be understood that the stacked chip package is not so limited and may comprise any suitable number of device ready wafers.

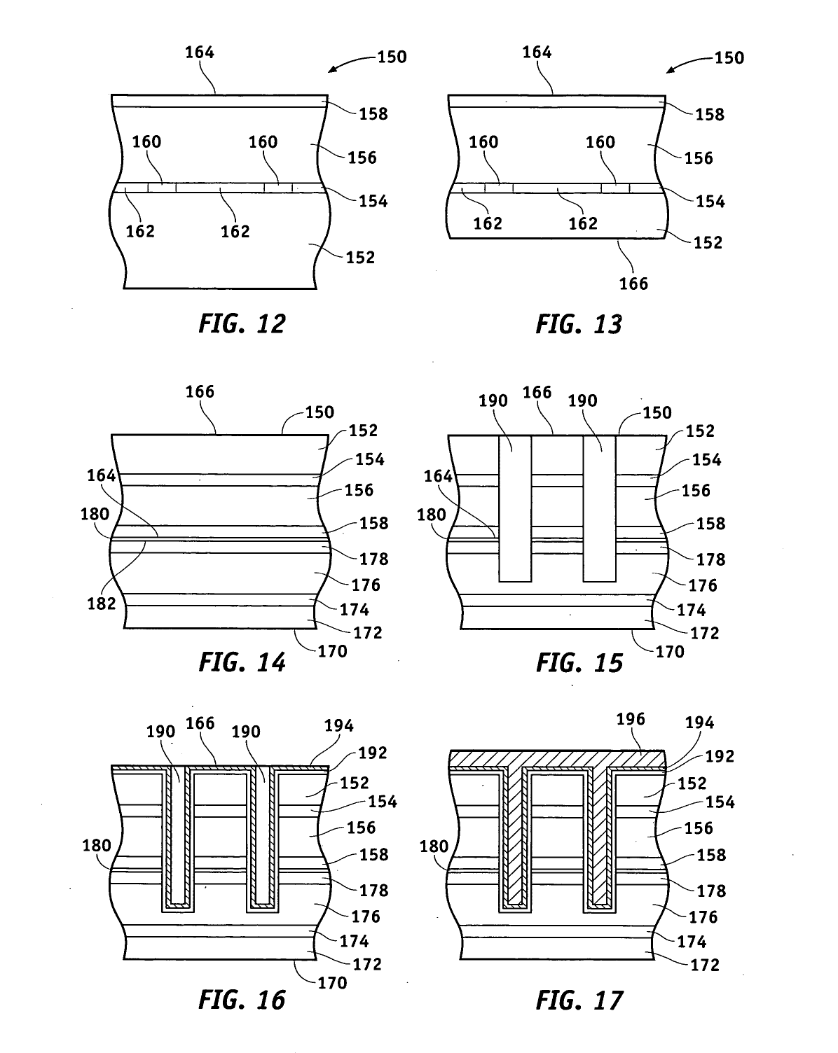

FIGS. 12-18 illustrate a method for fabricating a semiconductor package in accordance with another exemplary embodiment of the present invention. Referring to FIG. 12, the method begins with a first device-ready wafer 150 having a first surface 164. First device-ready wafer 150 may comprise a semiconductor substrate layer 152, which may be any suitable semiconductor substrate material, such as, for example, silicon or gallium arsenide, and may have any suitable thickness. A device layer 154 overlies substrate layer 152 and may comprise one or more device elements 160, such as transistors, memory devices, and the like, formed within an insulating material 162. A first dielectric layer 156 overlies device layer 154 and may comprise any suitable number of multi-level interconnects (not shown), including multi-level interconnects in electrical communication with device elements 160 disposed within device layer 154. Although shown as only single dielectric layers, first dielectric layer 156 and insulating material 162 each may be a single layer of dielectric material or may be composed of a plurality of layers of dielectric material, not all of which are necessarily the same material. First dielectric layer 156 may comprise any conventional dielectric material known in the semiconductor industry and may comprise the same dielectric material that forms insulating material 162. In accordance with one embodiment of the invention, first dielectric layer 156 may include a layer of low-k dielectric material. Preferably, first dielectric layer 156 comprises silicon dioxide. In one embodiment of the invention, first dielectric layer 156 and device layer 154 comprise one integral layer. In an alternative embodiment, first dielectric layer 156 and device layer 154 are two separate layers formed at different times. First device-ready wafer 150 may also comprise one or more device layers in addition to device layer 154 and may comprise one or more dielectric layers in addition to first dielectric layer 156.

In an optional embodiment of the present invention, first device-ready wafer 150 further may comprise a second dielectric layer 158 that overlies first dielectric layer 156. Second dielectric layer 158 serves as a barrier against diffusion of a subsequently deposited metal onto first device-ready wafer 150. Second dielectric layer 158 also may provide a substantially flat first surface 164 that facilitates the bonding of first surface 164 of first device-ready wafer 150 to a second device-ready wafer, as described in more detail below. Second dielectric layer 158 may be formed of any suitable, conventional dielectric material, such as, for example, silicon dioxide or silicon nitride

Referring to FIG. 13, a portion of semiconductor substrate 152 next is removed from a second surface 166 of wafer 150 using any of the methods described above with reference to the thinning of semiconductor substrate 12. Semiconductor substrate 152 may be thinned to any suitable thickness. In one embodiment of the invention, the semiconductor substrate 152 is thinned to a thickness of no greater than about 100 μm. In a preferred embodiment of the invention, the semiconductor substrate. 152 is thinned to a thickness of no greater than about 50 μm. In a more preferred embodiment, the semiconductor substrate 152 is thinned to a thickness of no greater than about 10 μm.

As illustrated in FIG. 14, wafer 150 then may be bonded to a second-device-ready wafer 170, which may or may not have been thinned as described above. Second device-ready wafer 170 also may comprise a semiconductor substrate layer 172, at least one device layer 174, at least one first dielectric layer 176 and, optionally, a second dielectric layer 178. The wafers are bonded using any conventional glue or adhesive 180 known in the semiconductor industry. In one embodiment of the invention, wafer 150 and wafer 170 are bonded “face-to-face”, that is, first surface 164 of wafer 150 is bonded to a first surface 182 of wafer 170, as illustrated in FIG. 14. In an alternative embodiment of the invention, wafer 150 and wafer 170 are bonded “face-to back”, that is, first surface 182 of wafer 170 is bonded to second surface 166 of wafer 150.

Referring to FIG. 15, at least one through-wafer via 190 is formed by conventional photolithographic techniques and etching techniques. Through-wafer via 190 extends from an exposed surface of wafer 150, such as first surface 166 as illustrated in FIG. 15, through wafer 150 and terminates within second wafer 170, preferably within the first dielectric layer 176. Through-wafer via 190 may have the same dimensions as those described above for through-wafer via 24 of FIG. 2.

Turning to FIG. 16, in one embodiment of the invention, a barrier layer 192 may be subsequently deposited overlying the bottom and sidewalls of through-wafer via 190 and the exposed surface 166 of first device-ready wafer 150. In another embodiment of the invention, after formation of barrier layer 192, a seed layer 194 of conductive material may be formed on barrier layer 192 overlying the sidewalls and bottom of through-wafer via 190 and the exposed surface 166 of first device-ready wafer 150. Barrier layer 192 may comprise any of the materials and may be formed in accordance with any of the processes described above for barrier layer 28 of FIG. 3. In one embodiment of the invention, barrier layer 192 may be formed of multiple layers, such as, for example, a layer of tantalum, tantalum nitride and/or titanium nitride deposited over a layer of silicon dioxide. Seed layer 194 may comprise any of the materials and may be formed in accordance with any of the processes described above for seed layer 30 of FIG. 4.

Next, as illustrated in FIG. 17, a layer of conductive material 196 is deposited overlying the seed layer 194 by the electrochemical mechanical deposition process described above with reference to FIG. 5. The conductive material layer 196 is formed from any suitable conductive material, such as copper, and preferably is formed of the same conductive material from which seed layer 194 is formed. In a more preferred embodiment, seed layer 194 and conductive material layer 196 both comprise copper. The electrochemical mechanical deposition process results in the deposition of the conductive material layer 196 to a sufficient thickness that through-wafer via 190 is completely filled with the conductive material, but with a relatively thin overburden.

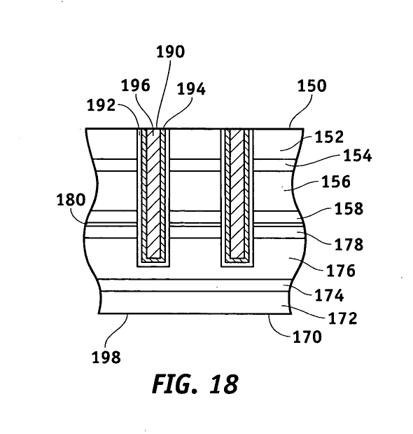

Following the deposition of conductive material layer 196 having a relatively thin overburden and a substantially planar upper surface, any excess conductive material and the barrier layer overlying surface 166 of wafer 150 are removed to achieve the desired structure illustrated in FIG. 18. Removal of the excess conductive material and barrier layer may be effected by CMP, ECMP, wet etching, or any other suitable conventional removal method. In one embodiment of the invention, a portion of the layer of wafer 150 underlying the excess conductive material and the barrier layer on surface 166 may be removed to ensure that the conductive material and barrier layer 192 have been substantially removed from surface 166. It will be appreciated that, before or after removal of the excess material from wafer 150, material may be removed from a second surface 198 of wafer 170, where second surface 198 is either a surface of substrate layer 172 or a surface proximate to first dielectric layer 176 or second dielectric layer 178.

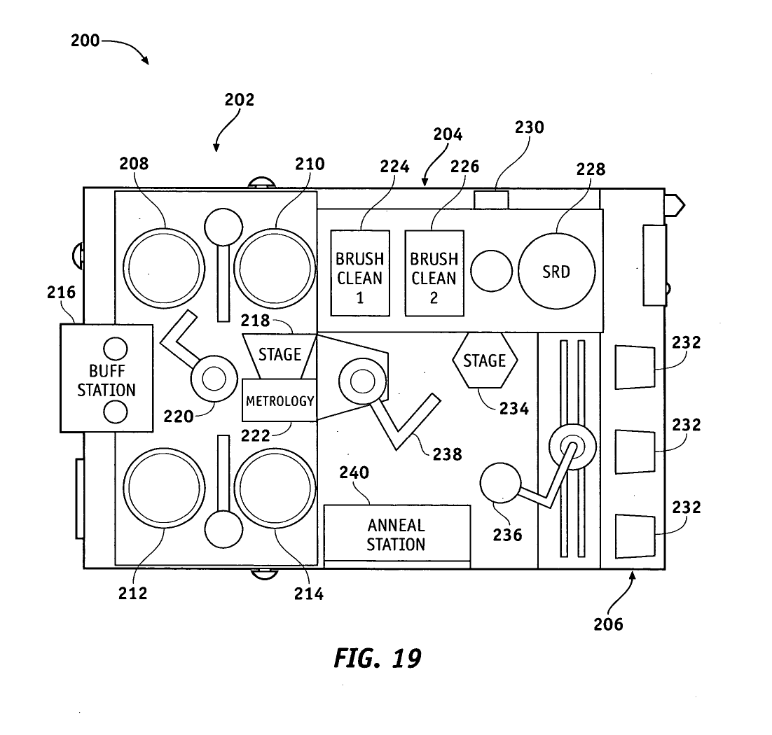

FIG. 19 illustrates a top cut-away view of a multi-process workpiece apparatus 200 that may be utilized to fabricate the semiconductor stacked packages of the present invention. The apparatus may be suitable for electrochemically mechanically depositing conductive material onto a surface of a device-ready wafer and/or removing any excess conductive material from the wafer. The apparatus may also be used for substrate grinding and seed layer enhancement. Apparatus 200 may include a multi-platen polishing system 202, a clean system 204, and a wafer load and unload station 206.

Exemplary multi-platen polishing system 202 may include four processing stations 208, 210, 212, and 214, which each operate independently; a buff station 216; a stage 218; a transport robot 220; and optionally, a metrology station 222 and an anneal station 240. Processing stations 208-214 may be configured as desired to perform specific functions; however, in accordance with the present invention, at least one of the processing stations 208-214 includes an electrochemical mechanical deposition apparatus, such as that illustrated in FIG. 11 or a substrate removal apparatus, such as a grinding apparatus or a wet etch apparatus. In addition, at least one of the processing stations 208-214 includes an apparatus configured to remove excess overburden on a workpiece, such as an apparatus used to perform CMP, ECMP, wet etching, and the like. The remaining processing stations may comprise apparatuses for a variety of other purposes. For example, in one embodiment of the invention, one of the remaining processing stations may comprise an apparatus for grinding semiconductor substrates in accordance with the present invention. Alternatively, or in addition, one of the remaining processing stations may comprise an apparatus for wet etching semiconductor substrates in accordance with the present invention. In yet another embodiment of the invention, one of the remaining stations may comprise an apparatus for seed layer enhancement. Alternatively, any one of the stations 208-214 may be used to perform more than one process, such as both seed layer enhancement and electrochemical mechanical deposition.

Clean station 204 is generally configured to remove debris such as slurry residue and material removed from the wafer surface during polishing. In accordance with the illustrated exemplary embodiment, station 204 includes brush cleaners 224 and 226, a spin rinse dryer 228, and a first robot 230. In an alternative embodiment of the present invention, not illustrated in FIG. 19, clean station 204 may include a carbon dioxide particle cleaner. Carbon dioxide particle cleaners are well known in the art and are configured to bombard wafers with carbon dioxide particles to remove foreign particulates from the wafer. Spin rinse dryer 228 may be configured for conventional spin rinsing and drying as is well known in the art; in another embodiment of the present invention, spin rinse dryer 228 may also be configured for bevel edge etching, as is also well known in the art.

Wafer load and unload station 206 is configured to receive dry wafers for processing in cassettes 232. In accordance with the present invention, the wafers are dry when loaded onto station 206 and are dry before return to station 206.

In accordance with an alternate embodiment of the invention, clean station 204 may be separate from the multi-process workpiece apparatus. In this case, load station 206 is configured to receive dry wafers for processing, but the wafers may remain in a wet state after plating or polishing and before transfer to a clean station.

In operation, cassettes 232, including one or more wafers, are loaded onto apparatus 200 at station 206. The wafers are then individually transported to a stage 234 using a second robot 236. A third robot 238 retrieves a wafer at stage 234 and transports the wafer to metrology station 222 for film characterization or to stage 218 within polishing system 202. Transport robot 220 picks up the wafer from metrology station 222 or stage 218 and transports the wafer to one of processing stations 208-214 for electrochemical mechanical deposition of a conductive material and/or thinning of a semiconductor substrate.

In another exemplary embodiment, the wafer may be transferred to one of processing stations 208-214 for seed layer enhancement before electrochemical mechanical deposition. Seed layer enhancement may be performed with an electric current or may be electroless, i.e., performed by chemical reduction in the absence of electric current. Exemplary processes for seed layer enhancement are described in U.S. Pat. No. 6,664,122, issued on Dec. 16, 2003 to Andryuschenko et al., which patent is incorporated herein in its entirety. Seed layer enhancement is well known in the art and, accordingly, will not be discussed further herein. Alternatively, both seed layer enhancement and electrochemical deposition may be performed at a single station.

After transfer to one of processing stations 208-214 for electrochemical mechanical deposition and after a desired amount of material is deposited onto the wafer surface, a portion of the deposited material and, if desired, other materials may be removed by transporting the wafer to another processing station 208-214 for CMP, ECMP, or wet etching. Alternatively, a deposition environment within one of the stations may be changed to an environment suitable for electrochemical planarization—e.g., by changing the solution and the bias applied to the wafer. In this case, a single polishing station may be used for both deposition of material and removal of material. Accordingly, a single layer polishing station may be used to perform seed layer enhancement, electrochemical mechanical deposition, and electrochemical planarization. The wafer then may be transported to yet another processing station 208-214 for thinning the semiconductor substrate. In an alternative embodiment of the invention, the wafer may be transported to one of the processing stations 208-214 to first thin the semiconductor substrate of the wafer and then transported to one or more stations 208-214 for seed layer enhancement, electrochemical mechanical deposition, electrochemical planarization, CMP and/or wet etching.

In a further exemplary embodiment of the invention, transport robot 220 may be configured with at least two end effectors (not shown), one end effector for transporting dirty wafers and one for transporting clean wafers. Because multi-process workpiece apparatus 100 may provide both electrochemical deposition stations and planarization stations, it is desirable to ensure the cleanliness of wafers before the wafers are subjected to deposition, as any particulates from slurry or by-products of planarization may adversely impact deposition. Accordingly, by way of example, transport robot 220 may receive a clean wafer from stage 218 using the clean end effector and may transport the wafer to one of processing stations 208-214 for electrochemical deposition. Using the same end effector, transport robot 220 may then transport the wafer to one of processing stations 208-214 for planarization, after which the dirty end effector of transport robot 220 may receive the wafer and transport it back to stage 218.

In an alternative embodiment of the present invention, multi-platen polishing system 202 may include a rinse station (not shown). The rinse station may be configured to clean the end effector of transport robot 220 or a wafer that it carries, or both the robot end effector and wafer simultaneously. The transport robot 220 may receive an unclean wafer from one of processing stations 208-214, access the rinse station and then transport the now clean wafer to another processing station 208-214, metrology station 222, buff station 216 or stage 218.

In accordance with another exemplary embodiment of the invention, after electrochemical deposition, the wafer may be transported by transport robot 220 from processing stations 208-214 to stage 218, where it is transported by third robot 238 to spin rinse dryer 228 for bevel edge etching, and/or rinsing and drying and then to anneal station 240 where the wafer may be annealed, as is well known in the art. Following annealing, third robot 238 may transport the wafer from anneal station 240 back to stage 218 where transport robot 220 receives it and transports it to one of processing stations 208-214 for chemical mechanical planarization, electrochemical planarization, wet etching, and/or grinding.

After conductive material has been deposited onto the wafer surface via electrochemical mechanical deposition and a desired amount of the material has been removed via electrochemical planarization, CMP or wet etching, the wafer may be transferred to buff station 216 to further polish the surface of the wafer. After the polishing and/or buff process, the wafer may be transferred to stage 218. In accordance with one embodiment of the invention, stage 218 is configured to maintain one or more wafers in a wet, e.g. deionized water, environment. The stage 218 is preferably configured with a plurality of slots or trays to hold several wafers at a time. The wet environment of stage 218 may be suitably maintained by providing spray nozzles for spraying the wafers with deionized water while in the slots. Alternatively, stage 218 could be configured in a bath type arrangement such that the slots and wafers are fully immersed in a bath of deionized wafer.

After a wafer is placed in stage 218, third robot 238 picks up the wafer and transports the wafer to clean system 204. In particular, third robot 238 transports the wafer to first robot 230, which in turn places the wafer in one of cleaners 224, 226. The wafer is cleaned using one or more cleaners 224, 226 and is then transported to spin rinse dryer 228 to rinse and dry the wafer prior to transporting the wafer to load/unload station 206 using robot 236.

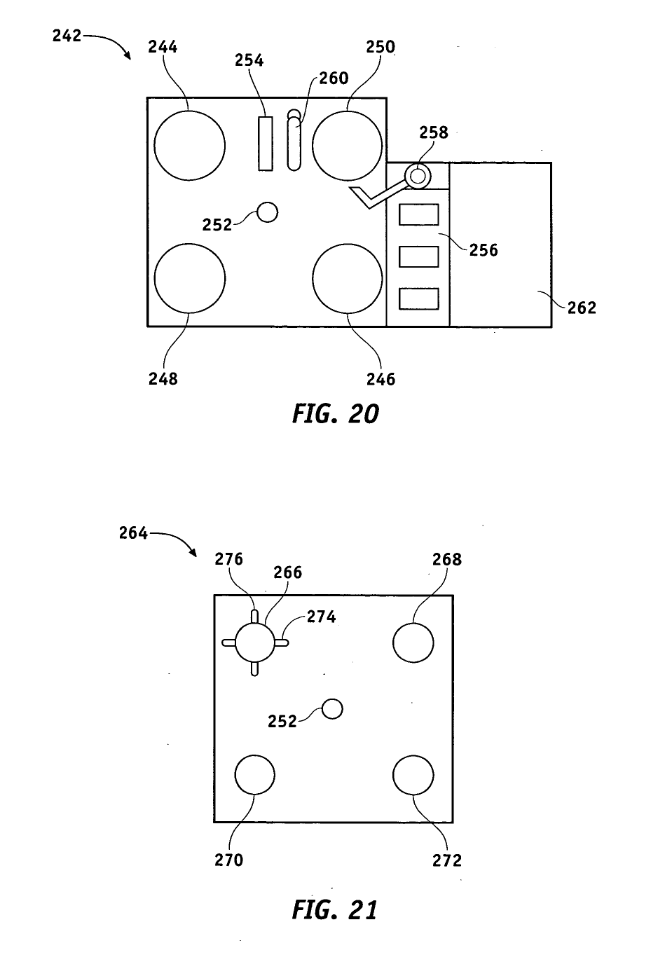

FIG. 20 illustrates a top cut-away view of another exemplary multi-process apparatus 242 configured to electrochemically deposit material onto a wafer surface and/or remove a portion of the deposited material. Apparatus 242 is suitably coupled to a carousel 264, illustrated in FIG. 21, to form an automated electrochemical mechanical deposition and/or thinning system. A system in accordance with this embodiment may also include a removable cover (not illustrated in figures) overlying apparatus 242 and 264.

Apparatus 242 includes at least three processing stations 244, 246, and 248. At least one of stations 244-248 is configured for electrochemical mechanical deposition and/or substrate removal. The other polishing stations may be configured for seed layer enhancement, CMP, ECMP, wet etching, and/or grinding. In addition, any one polishing station may be used to perform a number of processes such as, for example, electrochemical deposition and ECMP, or electroless seed layer enhancement, electrochemical deposition, and ECMP.

Apparatus 242 may also include a wafer transfer station 250, a center rotational post 252, which is coupled to carousel 264, and which operatively engages carousel 264 to cause carousel 264 to rotate, a load and unload station 256, a robot 258 and an anneal station 262. Furthermore, apparatus 242 may include one or more rinse washing stations 254 to rinse and/or wash a surface of a wafer and/or an end effector of robot 258 before or after a polishing or electrodeposition process. Although illustrated with three processing stations, apparatus 242 may include any desired number of processing stations. At least one of processing stations 244-248 may include a platen and a wafer contact surface attached thereto as described herein. In addition, at least one of processing stations 244-248 may include a conditioner 260 to condition the surface of the wafer contact surface. Wafer transfer station 250 is generally configured to stage wafers before or between deposition and/or material removal operations and may be further configured to wash and/or maintain the wafers in a wet environment.

Carousel apparatus 264 includes carriers 266, 268, 270, and 272, at least one of which is configured to hold a single wafer and urge the wafer against a wafer contact surface (e.g., a contact surface associated with one of stations 244-248). Each carrier 266-272 is suitably spaced from post 252, such that each carrier aligns with a processing station 244-248 or transfer station 250. In accordance with one embodiment of the invention, each carrier 266-272 is attached to a rotatable drive mechanism using a gimbal system (not illustrated), which allows carriers 266-272 to cause a wafer to rotate (e.g. during a deposition process). In addition, the carriers may be attached to a carrier motor assembly that is configured to cause the carriers to translate laterally—e.g., along tracks 274-276. In accordance with one aspect of this embodiment, each carrier 266-272 rotates and translates independently of the other carriers.

In operation, wafers are processed using apparatus 242 and 264 by loading a wafer onto station 250, from station 256, using robot 258. One of wafer carriers 266-272 is lowered over the wafer and a mechanism, such as a vacuum, is used so that the carrier may receive and engage the wafer. The wafer then is placed in contact with a seed layer enhancement station, an electrochemical mechanical deposition station, a CMP station, a wet etching station or a grinding station in accordance with the present invention. The wafer then may be transported to the other stations 244-248 for subsequent processing in accordance with various embodiments of the invention.

Accordingly, methods and apparatuses for fabricating semiconductor packaging utilizing through-wafer interconnect technology in accordance with the present invention have been described. The inventions provides for an efficient electrochemical deposition process that ensures substantial filling of through-wafer vias while minimizing undesirable overburden. The present invention thereby reduces, or eliminates, the need for subsequent material removal. While at least one exemplary embodiment has been presented in the foregoing detailed description of the invention, it should be appreciated that a vast number of variations exist. It should also be appreciated that the exemplary embodiment or exemplary embodiments are only examples, and are not intended to limit the scope, applicability, or configuration of the invention in any way. Rather, the foregoing detailed description will provide those skilled in the art with a convenient road map for implementing an exemplary embodiment of the invention, it being understood that various changes may be made in the function and arrangement of elements described in an exemplary embodiment without departing from the scope of the invention as set forth in the appended claims.

What is claimed is:

1. A method of forming a through-wafer via interconnect in a device-ready wafer, the method comprising:
etching a via extending from a first surface of the device-ready wafer and terminating within the device-ready wafer;
contacting the first surface of the device-ready wafer with a wafer contact surface while causing relative motion between the device-ready wafer and the wafer contact surface;
supplying an electrochemical deposition composition to the first surface of the device-ready wafer, the electrochemical deposition composition comprising a conductive material;
applying an electric potential difference between the first surface of the device-ready wafer and an anode, the device-ready wafer disposed proximate to the anode;
causing the conductive material to deposit within the via; and
removing a portion of the device-ready wafer from a second surface of the device-ready wafer to expose the conductive material within the via.

2. The method of forming a through-wafer via interconnect in a device-ready wafer of claim 1, wherein, during the step of causing the conductive material to deposit within the via, conductive material is also caused to deposit on the first surface of the device-ready wafer, and wherein the method further comprises the step of substantially removing the conductive material from the first surface of the device-ready wafer.

3. The method of forming a through-wafer via interconnect in a device-ready wafer of claim 2, wherein the step of substantially removing the conductive material comprises the step of removing the conductive material by at least one of CMP, ECMP, and wet etching.

4. The method of forming a through-wafer via interconnect in a device-ready wafer of claim 1, wherein the device-ready wafer comprises a semiconductor substrate and wherein the step of etching a via extending from a first surface of the device-ready wafer and terminating within the device-ready wafer comprises the step of etching the via to terminate within the semiconductor substrate.

5. The method of forming a through-wafer via interconnect in a device-ready wafer of claim 1, wherein the step of contacting the first surface of the device-ready wafer with a wafer contact surface comprises the step of contacting the first surface of the device-ready wafer with a polishing pad.

6. The method of forming a through-wafer via interconnect in a device-ready wafer of claim 1, wherein the step of contacting the first surface of the device-ready wafer with a wafer contact surface while causing relative motion between the device-ready wafer and the wafer contact surface comprises the step of causing at least one of orbital, rotational, oscillatory, and lateral motion between the device-ready wafer and the wafer contact surface.

7. The method of forming a through-wafer via interconnect in a device-ready wafer of claim 1, wherein the step of supplying an electrochemical deposition composition comprises the step of supplying an electrochemical deposition composition formed of a metal salt, a suppressor, an accelerator, and an electrolyte.

8. The method of forming a through-wafer via interconnect in a device-ready wafer of claim 1, the electrochemical deposition composition formed of a metal salt, a suppressor, and an electrolyte, wherein the method further comprises the steps of applying an accelerator to the device-ready wafer and removing the accelerator from the first surface of the device-ready wafer and wherein the steps of applying an accelerator and removing the accelerator are performed after the step of etching a via.

9. The method of forming a through-wafer via interconnect in a device-ready wafer of claim 1, further comprising the step of forming a dielectric layer overlying the first surface of the device-ready wafer and within the via, the step of forming a dielectric layer performed after the step of etching a via.

10. The method of forming a through-wafer via interconnect in a device-ready wafer of claim 9, further comprising the step forming a barrier layer overlying the dielectric layer within the via.

11. The method of forming a through-wafer via interconnect in a device-ready wafer of claim 1, further comprising the step of forming a seed layer overlying the first surface of the device-ready wafer and within the via, the step of forming a seed layer performed after the step of etching a via.

12. The method of forming a through-wafer via interconnect in a device-ready wafer of claim 1, wherein the step of supplying an electrochemical deposition composition to the first surface of the device-ready wafer, the electrochemical deposition composition comprising a conductive material, comprises the step of supplying an electrochemical deposition composition comprising copper.

13. The method of forming a through-wafer via interconnect in a device-ready wafer of claim 1, wherein the step of removing a portion of the device-ready wafer from a second surface of the device-ready wafer comprises the step of removing a portion of the device-ready wafer from a second surface of the- device-ready wafer by at least one of grinding, CMP, EMCP, and wet etching.

14. The method of forming a through-wafer via interconnect in a device-ready wafer of claim 1, the method further comprising the step of affixing the first surface of the device-ready wafer to a work piece before the step of etching a via, wherein the step of etching a via comprises etching a via extending from a surface of the work piece and terminating within the device-ready wafer.

15. The method of forming a through-wafer via interconnect in a device-ready wafer of claim 14, wherein the step of affixing the device-ready wafer to a work piece comprises the step of affixing the device-ready wafer to another device-ready wafer.

16. The method of forming a through-wafer via interconnect in a device-ready wafer of claim 1, the method further comprising affixing the device-ready wafer to a work piece after the step of removing a portion of the device-ready wafer from a second surface.

17. The method of forming a through-wafer via interconnect in a device-ready wafer of claim 16, wherein the step of affixing the device-ready wafer to a work piece comprises the step of affixing the device-ready wafer to another device-ready wafer.

18. A method of forming a chip stack utilizing a first device-ready wafer, the method comprising:
etching a via extending from a first surface of the first device-ready wafer and terminating within the first device-ready wafer;
performing electrochemical mechanical deposition on the first device-ready wafer, the step of electrochemical mechanical deposition comprising:
contacting the first surface of the first device-ready wafer with a wafer contact surface while causing relative motion between the first device-ready wafer and the wafer contact surface:
supplying an electrochemical deposition composition to the first device-ready wafer, the electrochemical deposition composition comprising a conductive material; and
applying an electric potential difference between the first device-ready wafer and an anode, the first device-ready wafer disposed proximate to the anode, wherein the conductive material is deposited within the via and on the first surface of the first device-ready wafer;
substantially removing the conductive material from the first surface of the first device-ready wafer;
removing a portion of the first device-ready wafer from a second surface of the first device-ready wafer to expose the conductive material within the via;
aligning the via of the first device-ready wafer to a via of a second device-ready assembly; and
affixing the first device-ready wafer to the second device-ready assembly.

19. The method of forming a chip stack of claim 18, wherein the first device-ready wafer comprises a dielectric layer and the step of etching a via comprises etching a via extending from a surface of the dielectric layer.

20. The method of forming a chip stack of claim 18, wherein the first device-ready wafer comprises a substrate layer and the step of etching a via comprises etching a via terminating within the substrate layer.

21. The method of forming a chip stack of claim 18, the step of etching a via comprising etching a via having a width in the range of from about 0.1 μm to about 150 μm.

22. The method of forming a chip stack of claim 18, further comprising the step of forming a barrier layer within the via before the step of performing electrochemical mechanical deposition and wherein the step of substantially removing the conductive material from the first surface of the first device-ready wafer comprises substantially removing the conductive material and the barrier layer from the first surface of the first device-ready wafer.

23. The method of forming a chip stack of claim 18, further comprising the step of depositing a seed layer within the via before the step of performing electrochemical mechanical deposition and wherein the step of substantially removing the conductive material from the first surface of the first device-ready wafer comprises substantially removing the conductive material and the seed layer from the first surface of the first device-ready wafer.

24. The method of forming a chip stack of claim 18, wherein the step of supplying an electrochemical deposition composition comprises supplying an electrochemical deposition composition formed of a metal salt, a suppressor, an accelerator, and an electrolyte.

25. The method of forming a chip stack of claim 18, wherein the electrochemical deposition composition comprises a metal salt, a suppressor, and an electrolyte, and wherein the method further comprises the step of applying an accelerator to the first device-ready wafer after the step of etching a via.

26. The method of forming a chip stack of claim 25, further comprising the step of substantially removing the accelerator from the first surface of the first device-ready wafer after the step of applying the accelerator to the first device-ready wafer.

27. The method of forming a chip stack of claim 25, further comprising the step of substantially removing the accelerator from the first surface of the first device-ready wafer during the step of applying the accelerator to the first device-ready wafer.

28. The method of forming a chip stack of claim 25, further comprising the step of substantially removing the accelerator from the first surface of the first device-ready wafer before the step of supplying an electrochemical deposition composition to the first device-ready wafer.

29. The method of forming a chip stack of claim 25, further comprising the step of substantially removing the accelerator from the first surface of the first device-ready wafer during the step of supplying an electrochemical deposition composition to the first device-ready wafer.

30. The method of forming a chip stack of claim 18, wherein the step of aligning the via of the first device-ready wafer to a via of a second device-ready assembly comprises the step of aligning the via of the first device-ready wafer to a via of a second device-ready assembly having at least one device-ready wafer.

31. The method of forming a chip stack of claim 18, the step of affixing the first device-ready wafer to the second device-ready assembly comprises affixing the first surface of the first device-ready wafer to the second device-ready wafer.

32. The method of forming a chip stack of claim 18, the step of affixing the first device-ready wafer to the second device-ready assembly comprises affixing the second surface of the first device-ready wafer to the second device-ready assembly.

33. The method of forming a chip stack of claim 18, wherein the step of substantially removing the conductive material from the first surface of the first device-ready wafer comprises the step of removing the conductive material by at least one of CMP, ECMP, and wet etching.

34. The method of forming a chip stack of claim 18, further comprising the step of affixing the first surface of the first device-ready wafer to a work piece before the step of etching a via, and wherein the step of etching a via comprises etching a via extending from a surface of the work piece and terminating within the first device-ready wafer.

35. The method of forming a chip stack of claim 18, wherein the step of contacting the first surface of the first device-ready wafer with a wafer contact surface comprises the step of contacting the first surface of the first device-ready wafer with a polishing pad.

36. The method of forming a chip stack of claim 18, wherein the step of removing a portion of the first device-ready wafer from a second surface of the first device-ready wafer comprises the step of removing a portion of the first device-ready wafer by at least one of grinding, CMP, ECMP, and wet etching.

37. A method of forming a semiconductor package from a first device-ready wafer having a substrate, the method comprising:
removing a portion of the substrate from the first device-ready wafer;
affixing a first surface of the first device-ready wafer to a first surface of a second device-ready assembly;
etching a via extending from a second surface of the first device-ready wafer through the first device-ready wafer and terminating within the second device-ready wafer;
performing electrochemical mechanical deposition, the step of electrochemical mechanical deposition comprising:
contacting the second surface of the first device-ready wafer with a wafer contact surface while causing relative motion between the first device-ready wafer and the wafer contact surface;
supplying an electrochemical deposition composition to the second surface of the first device-ready wafer, the electrochemical deposition composition comprising a conductive material; and
applying an electric potential difference between of the second surface of the first device-ready wafer and an anode, the first device-ready wafer disposed proximate to the anode, wherein the conductive material is deposited within the via and on the second surface of the first device-ready wafer; and
substantially removing the conductive material from the second surface of the first device-ready wafer.

38. The method of forming a semiconductor package of claim 37, further comprising the step of forming a dielectric layer within the via after the step of etching a via.

39. The method of forming a semiconductor package of claim 37, further comprising the step of forming a barrier layer within the via before the step of performing electrochemical mechanical deposition and wherein the step of substantially removing the conductive material from the second surface of the first device-ready wafer comprises the step of substantially removing the conductive material and the barrier layer from the second surface of the first device-ready wafer.

40. The method of forming a semiconductor package of claim 37, further comprising the step of depositing a seed layer within the via before the step of performing electrochemical mechanical deposition and wherein the step of substantially removing the conductive material from the second surface of the first device-ready wafer comprises the step of substantially removing the conductive material and the seed layer from the second surface of the first device-ready wafer.

41. The method of forming a semiconductor package of claim 37, wherein the step of supplying an electrochemical deposition composition comprises the step of supplying an electrochemical deposition composition comprising a metal salt, a suppressor, an accelerator and an electrolyte.

42. The method of forming a semiconductor package of claim 37, wherein the electrochemical deposition composition comprises a metal salt, a suppressor, and an electrolyte, and wherein the method further comprises the step of supplying an accelerator to the first device-ready wafer after the step of etching a via.

43. The method of forming a semiconductor package of claim 42, further comprising the step of substantially removing the accelerator from the second surface of the first device-ready wafer after the step of applying the accelerator to the first device-ready wafer.

44. The method of forming a semiconductor package of claim 42, further comprising the step of substantially removing the accelerator from the second surface of the first device-ready wafer during the step of applying the accelerator to the first device-ready wafer.

45. The method of forming a semiconductor package of claim 42, further comprising the step of substantially removing the accelerator from the second surface of the first device-ready wafer before the step of supplying an electrochemical deposition composition to the first device-ready wafer.

46. The method of forming a semiconductor package of claim 42, further comprising the step of substantially removing the accelerator from the second surface of the first device-ready wafer during the step of supplying an electrochemical deposition composition to the first device-ready wafer.

47. The method of forming a semiconductor package of claim 37, wherein the step of removing a portion of the substrate from the first device-ready wafer comprises removing a portion of the substrate from the first device-ready wafer so that the substrate has a thickness no greater than about 100 μm.

48. An apparatus used to form a semiconductor package comprising a device-ready wafer having a through-wafer via interconnect disposed therein, the apparatus comprising:
a chemical mechanical planarization apparatus;
a substrate removal apparatus configured for removal a portion of a substrate of the device-ready wafer; and
a wafer handling robot configured to transport the device-ready wafer between the chemical mechanical planarization apparatus and the substrate removal apparatus.

49. The apparatus used to form a semiconductor package of claim 48, the apparatus further comprising an electrochemical mechanical deposition apparatus having a platen, a conductive member overlying the platen, a wafer contact surface overlying the conductive member, at least one electrical conductor configured to be disposed proximate to a surface of a device-ready wafer, and a source of potential configured to apply an electrical potential difference between the device-ready wafer and the conductive member.

50. The apparatus used to form a semiconductor package of claim 48, wherein the substrate removal apparatus comprises a grinding apparatus.

51. The apparatus used to form a semiconductor package of claim 50, further comprising an apparatus configured for wet etching.

52. The apparatus used to form a semiconductor package of claim 48, wherein the substrate removal apparatus comprises an apparatus configured for wet etching.

53. The apparatus used to form a semiconductor package of claim 48, wherein the substrate removal apparatus comprises an electrochemical planarization apparatus.

54. The apparatus used to form a semiconductor package of claim 48, further comprising a seed layer enhancement apparatus.

55. The apparatus used to form a semiconductor package of claim 48, further comprising an anneal apparatus configured for annealing the device-ready wafer.

56. The apparatus used to form a semiconductor package of claim 48, further comprising a cleaning apparatus configured for cleaning the device-ready wafer.
